(19) United States
(12) Patent Application Publication
(10) Pub. No.: US 2024/0303402 A1
(43) Pub. Date: Sep. 12, 2024

(54) SHAPE MATCHING-BASED LAYOUT VERSUS SCHEMATIC FOR PHOTONIC CIRCUITS

(71) Applicant: Siemens Industry Software Inc., Plano, TX (US)

(72) Inventors: John G. Ferguson, Tualatin, OR (US); Basma Serry, Cairo (EG)

(73) Assignee: Siemens Industry Software Inc., Plano, TX (US)

(21) Appl. No.: 18/576,426

(22) PCT Filed: Jul. 13, 2021
(86) PCT No.: PCT/US2021/041399

§ 371 Date: Jan. 4, 2024

(51) Int. Cl. G06F 30/327; G06F 30/33

(52) U.S. Cl. CPC G06F 30/327; G06F 30/33

(57) ABSTRACT

A preliminary netlist comprising the photonic devices and location and rotation information for each of the photonic devices is extracted from the original layout design. In the extraction, each of the photonic devices is treated as a black box. A geometric pattern for the each of the photonic devices is then identified in a group of geometric patterns for each of the photonic devices based on physical properties of the each of the photonic devices specified in the circuit design. A new layout design is generated based on the identified geometric pattern for each of the photonic devices, the location and rotation information for each of the photonic devices, and the preliminary netlist. Geometric elements in each of the photonic devices in the new layout design are compared with corresponding geometric elements in the original layout design.

### FIELD OF THE DISCLOSED TECHNOLOGY

The present disclosed technology relates to the field of circuit design and manufacture. Various implementations of the disclosed technology may be particularly useful for verifying layout designs containing curvilinear features.

### BACKGROUND OF THE DISCLOSED TECHNOLOGY

Silicon photonics, combining large-scale photonic integration with large-scale electronic integration, can impact areas such as telecommunications, data centers and high-performance computing. Photonics-based computing consumes less energy and transmits data faster than pure electronics-based computing. Silicon photonics designs are often drawn with curved shapes. By contrast, a layout design for conventional circuits contains mainly Manhattan shapes, of which edges are parallel to the x and y axes. In addition to being widely in silicon photonics, curvilinear patterns can also offer better lithographic quality than Manhattan patterns. Memory chip making has started to explore curvilinear patterns. Due to the practical needs and advantages for using curvilinear patterns, the mask making industry has made progress with the introduction of multi-beam mask writers for writing curvilinear patterns on a mask. But conventional physical verification tools such as design rule checking (DRC) and layout-versus-schematic (LVS) are developed to process mainly Manhattan shapes. To better detect and validate photonic devices, improvements on physical verification techniques are needed.

### BRIEF SUMMARY OF THE DISCLOSED TECHNOLOGY

Various aspects of the present disclosed technology relate to techniques for applying layout versus schematic verification to photonic devices. In one aspect, there is a method comprising: receiving a circuit design and an original layout design derived from the circuit design, the circuit design comprising photonic devices, the photonic devices comprising waveguides; extracting a preliminary netlist comprising the photonic devices and location and rotation information for each of the photonic devices from the original layout design, wherein the extracting a preliminary netlist treats each of the photonic devices as a black box; identifying, in a group of geometric patterns for each of the photonic devices, a geometric pattern for the each of the photonic devices based on physical properties of the each of the photonic devices specified in the circuit design; generating a new layout design based on the identified geometric pattern for each of the photonic devices, the location and rotation information for each of the photonic devices, and the preliminary netlist; comparing geometric elements in each of the photonic devices in the new layout design with corresponding geometric elements in the original layout design; and storing results of the comparing.

The method may further comprise: repairing problems identified in the results of the comparing.

The extracting a preliminary netlist may comprise verifying connectivity between the photonic devices.

The group of geometric patterns may be generated by using a layout editing tool to create one geometric pattern for a type of the each of the photonic devices and then to vary physical properties of the one geometric pattern to generate more geometric patterns for the type of the each of the photonic devices.

Photonic devices in the photonic devices that are of the same type but have different rotational angles may be treated as different photonic devices.

In another aspect, there is one or more computer-readable media storing computer-executable instructions for causing one or more processors to perform the above method.

In still another aspect, there is a system, comprising: one or more processors, the one or more processors programmed to perform the above method.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclosed technology. Thus, for example, those skilled in the art will recognize that the disclosed technology may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 illustrates an example of a computing system that may be used to implement various embodiments of the disclosed technology.

FIG. 2 illustrates an example of a multi-core processor unit that may be used to implement various embodiments of the disclosed technology.

FIG. 3 illustrates an example of a layout versus schematic tool that may be implemented according to various embodiments of the disclosed technology.

FIG. 4 illustrates a flowchart showing a process of layout versus schematic for photonic devices that may be implemented according to various examples of the disclosed technology.

FIG. 5 illustrates an example of an overlap between two ring resonators.

FIG. 6A illustrates an example of a group of geometric patterns for a Bend90 device.

FIG. 6B illustrates an example of a group of geometric patterns for a ring resonator device.

FIG. 7A illustrates an example of an original layout design for a circuit design.

FIG. 7B illustrates an example of a layout design generated by placing the geometric patterns identified from the groups of geometric patterns based on the location and rotation information and the preliminary netlist extracted from the layout deign shown in FIG. 7A.

### DETAILED DESCRIPTION OF THE DISCLOSED TECHNOLOGY

### GENERAL Considerations

Various aspects of the present disclosed technology relate to techniques for applying layout versus schematic verification to photonic devices. In the following description, numerous details are set forth for the purpose of explanation. However, one of ordinary skill in the art will realize that the disclosed technology may be practiced without the use of these specific details. In other instances, well-known features have not been described in detail to avoid obscuring the present disclosed technology.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. Moreover, for the sake of simplicity, the disclosed flow charts and block diagrams typically do not show the various ways in which particular methods can be used in conjunction with other methods. Additionally, the detailed description sometimes uses terms like “extract”, “identify”, and “generate” to describe the disclosed methods. Such terms are high-level abstractions of the actual operations that are performed. The actual operations that correspond to these terms will vary depending on the particular implementation and are readily discernible by one of ordinary skill in the art.

Also, as used herein, the term “design” is intended to encompass data describing an entire integrated circuit device. This term also is intended to encompass a smaller group of data describing one or more components of an entire device, however, such as a portion of an integrated circuit device. Still further, the term “design” also is intended to encompass data describing more than one micro device, such as data to be used to form multiple micro devices on a single wafer.

### Illustrative Operating Environment

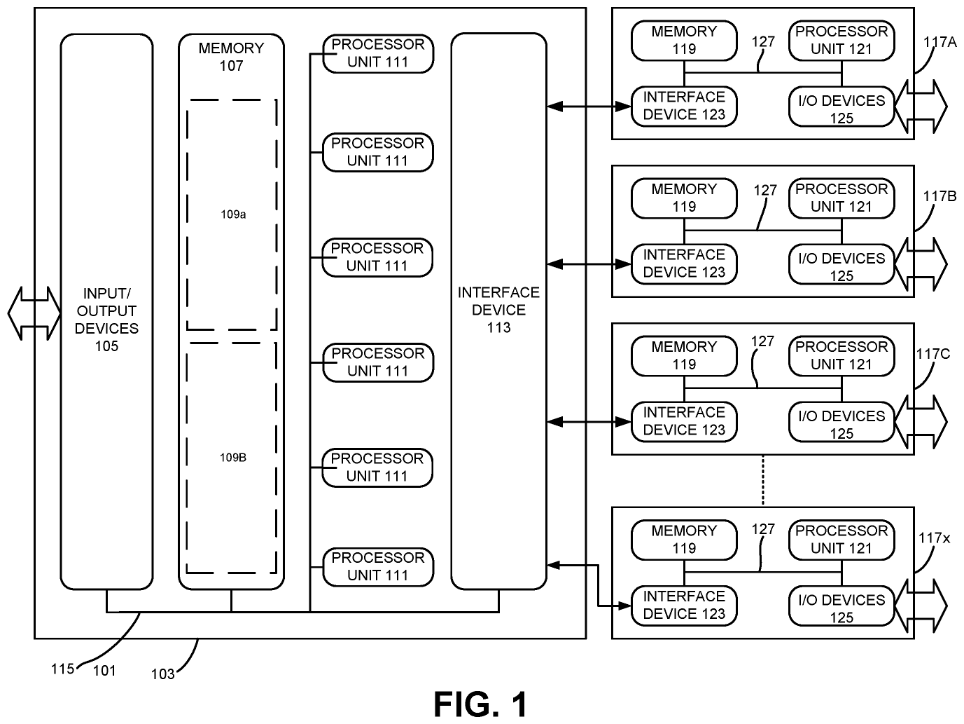

The execution of various electronic design automation processes according to embodiments of the disclosed technology may be implemented using computer-executable software instructions executed by one or more programmable computing devices. Because these embodiments of the disclosed technology may be implemented using software instructions, the components and operation of a generic programmable computer system on which various embodiments of the disclosed technology may be employed will first be described. Further, because of the complexity of some electronic design automation processes and the large size of many circuit designs, various electronic design automation tools are configured to operate on a computing system capable of simultaneously running multiple processing threads. The components and operation of a computer network having a host or master computer and one or more remote or servant computers therefore will be described with reference to FIG. 1. This operating environment is only one example of a suitable operating environment, however, and is not intended to suggest any limitation as to the scope of use or functionality of the disclosed technology.

In FIG. 1, the computer network 101 includes a master computer 103. In the illustrated example, the master computer 103 is a multi-processor computer that includes a plurality of input and output devices 105 and a memory 107. The input and output devices 105 may include any device for receiving input data from or providing output data to a user. The input devices may include, for example, a keyboard, microphone, scanner or pointing device for receiving input from a user. The output devices may then include a display monitor, speaker, printer or tactile feedback device. These devices and their connections are well known in the art, and thus will not be discussed at length here.

The memory 107 may similarly be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information.

As will be discussed in detail below, the master computer 103 runs a software application for performing one or more operations according to various examples of the disclosed technology. Accordingly, the memory 107 stores software instructions 109A that, when executed, will implement a software application for performing one or more operations. The memory 107 also stores data 109B to be used with the software application. In the illustrated embodiment, the data 109B contains process data that the software application uses to perform the operations, at least some of which may be parallel.

The master computer 103 also includes a plurality of processor units 111 and an interface device 113. The processor units 111 may be any type of processor device that can be programmed to execute the software instructions 109A, but will conventionally be a microprocessor device. For example, one or more of the processor units 111 may be a commercially generic programmable microprocessor, such as Intel® Pentium® or Xeon™ microprocessors, Advanced Micro Devices Athlon™ microprocessors or Motorola 68K/Coldfire® microprocessors. Alternately or additionally, one or more of the processor units 111 may be a custom-manufactured processor, such as a microprocessor designed to optimally perform specific types of mathematical operations. The interface device 113, the processor units 111, the memory 107 and the input/output devices 105 are connected together by a bus 115.

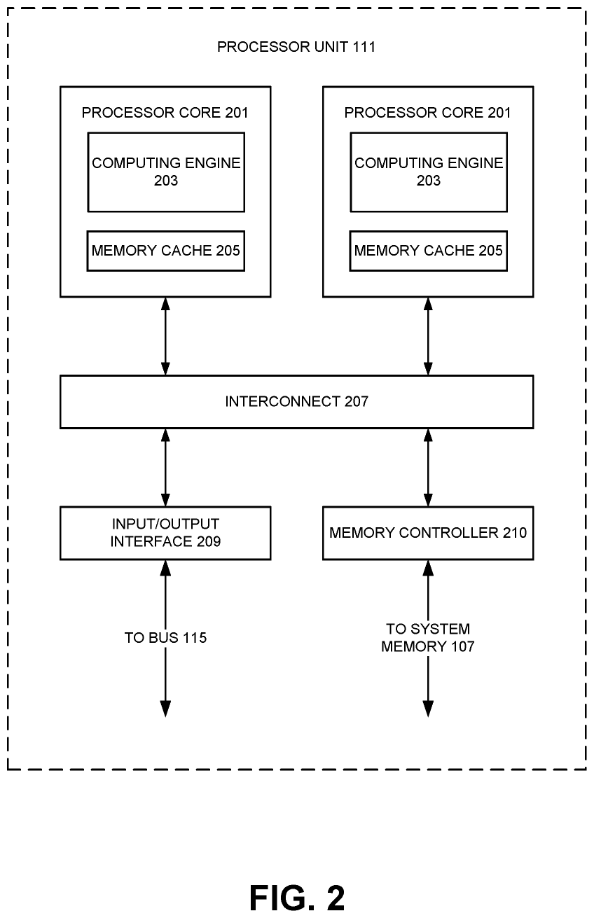

With some implementations of the disclosed technology, the master computing device 103 may employ one or more processing units 111 having more than one processor core. Accordingly, FIG. 2 illustrates an example of a multi-core processor unit 111 that may be employed with various embodiments of the disclosed technology. As seen in this figure, the processor unit 111 includes a plurality of processor cores 201. Each processor core 201 includes a computing engine 203 and a memory cache 205. As known to those of ordinary skill in the art, a computing engine contains logic devices for performing various computing functions, such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203 may then use its corresponding memory cache 205 to quickly store and retrieve data and/or instructions for execution.

Each processor core 201 is connected to an interconnect 207. The particular construction of the interconnect 207 may vary depending upon the architecture of the processor unit 111. With some processor cores 201, such as the Cell microprocessor created by Sony Corporation, Toshiba Corporation and IBM Corporation, the interconnect 207 may be implemented as an interconnect bus. With other processor units 111, however, such as the Opteron™ and Athlon™ dual-core processors available from Advanced Micro Devices of Sunnyvale, California, the interconnect 207 may be implemented as a system request interface device. In any case, the processor cores 201 communicate through the interconnect 207 with an input/output interface 209 and a memory controller 210. The input/output interface 209 provides a communication interface between the processor unit 111 and the bus 115. Similarly, the memory controller 210 controls the exchange of information between the processor unit 111 and the system memory 107. With some implementations of the disclosed technology, the processor units 111 may include additional components, such as a high-level cache memory accessible shared by the processor cores 201.

While FIG. 2 shows one illustration of a processor unit 111 that may be employed by some embodiments of the disclosed technology, it should be appreciated that this illustration is representative only, and is not intended to be limiting. Also, with some implementations, a multi-core processor unit 111 can be used in lieu of multiple, separate processor units 111. For example, rather than employing six separate processor units 111, an alternate implementation of the disclosed technology may employ a single processor unit 111 having six cores, two multi-core processor units each having three cores, a multi-core processor unit 111 with four cores together with two separate single-core processor units 111, etc.

Returning now to FIG. 1, the interface device 113 allows the master computer 103 to communicate with the servant computers 117A, 117B, 117C . . . 117x through a communication interface. The communication interface may be any suitable type of interface including, for example, a conventional wired network connection or an optically transmissive wired network connection. The communication interface may also be a wireless connection, such as a wireless optical connection, a radio frequency connection, an infrared connection, or even an acoustic connection. The interface device 113 translates data and control signals from the master computer 103 and each of the servant computers 117 into network messages according to one or more communication protocols, such as the transmission control protocol (TCP), the user datagram protocol (UDP), and the Internet protocol (IP). These and other conventional communication protocols are well known in the art, and thus will not be discussed here in more detail.

Each servant computer 117 may include a memory 119, a processor unit 121, an interface device 123, and, optionally, one more input/output devices 125 connected together by a system bus 127. As with the master computer 103, the optional input/output devices 125 for the servant computers 117 may include any conventional input or output devices, such as keyboards, pointing devices, microphones, display monitors, speakers, and printers. Similarly, the processor units 121 may be any type of conventional or custom-manufactured programmable processor device. For example, one or more of the processor units 121 may be commercially generic programmable microprocessors, such as Intel® Pentium® or Xeon™ microprocessors, Advanced Micro Devices Athlon™ microprocessors or Motorola 68K/Coldfire® microprocessors. Alternately, one or more of the processor units 121 may be custom-manufactured processors, such as microprocessors designed to optimally perform specific types of mathematical operations. Still further, one or more of the processor units 121 may have more than one core, as described with reference to FIG. 2 above. For example, with some implementations of the disclosed technology, one or more of the processor units 121 may be a Cell processor. The memory 119 then may be implemented using any combination of the computer readable media discussed above. Like the interface device 113, the interface devices 123 allow the servant computers 117 to communicate with the master computer 103 over the communication interface.

In the illustrated example, the master computer 103 is a multi-processor unit computer with multiple processor units 111, while each servant computer 117 has a single processor unit 121. It should be noted, however, that alternate implementations of the disclosed technology may employ a master computer having single processor unit 111. Further, one or more of the servant computers 117 may have multiple processor units 121, depending upon their intended use, as previously discussed. Also, while only a single interface device 113 or 123 is illustrated for both the master computer 103 and the servant computers, it should be noted that, with alternate embodiments of the disclosed technology, either the computer 103, one or more of the servant computers 117, or some combination of both may use two or more different interface devices 113 or 123 for communicating over multiple communication interfaces.

With various examples of the disclosed technology, the master computer 103 may be connected to one or more external data storage devices. These external data storage devices may be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information. According to some implementations of the disclosed technology, one or more of the servant computers 117 may alternately or additionally be connected to one or more external data storage devices. Typically, these external data storage devices will include data storage devices that also are connected to the master computer 103, but they also may be different from any data storage devices accessible by the master computer 103.

It also should be appreciated that the description of the computer network illustrated in FIG. 1 and FIG. 2 is provided as an example only, and it not intended to suggest any limitation as to the scope of use or functionality of alternate embodiments of the disclosed technology.

### Circuit Design Flow

Electronic circuits, such as integrated microcircuits, are used in a variety of products, from automobiles to microwaves to personal computers. Designing and fabricating integrated circuit devices typically involves many steps, sometimes referred to as a “design flow.” The particular steps of a design flow often are dependent upon the type of integrated circuit, its complexity, the design team, and the integrated circuit fabricator or foundry that will manufacture the microcircuit. Typically, software and hardware “tools” verify the design at various stages of the design flow by running software simulators and/or hardware emulators. These steps aid in the discovery of errors in the design, and allow the designers and engineers to correct or otherwise improve the design.

Several steps are common to most design flows. Initially, the specification for a new circuit is transformed into a logical design, sometimes referred to as a register transfer level (RTL) description of the circuit. With this logical design, the circuit is described in terms of both the exchange of signals between hardware registers and the logical operations that are performed on those signals. The logical design typically employs a Hardware Design Language (HDL), such as the Very high speed integrated circuit Hardware Design Language (VHDL). The logic of the circuit is then analyzed, to confirm that it will accurately perform the functions desired for the circuit. This analysis is sometimes referred to as “functional verification.”

After the accuracy of the logical design is confirmed, it is converted into a device design by synthesis software. The device design, which is typically in the form of a schematic or netlist, describes the specific electronic devices (such as transistors, resistors, and capacitors) that will be used in the circuit, along with their interconnections. This device design generally corresponds to the level of representation displayed in conventional circuit diagrams. The relationships between the electronic devices are then analyzed, to confirm that the circuit described by the device design will correctly perform the desired functions. This analysis is sometimes referred to as “formal verification.” Additionally, preliminary timing estimates for portions of the circuit are often made at this stage, using an assumed characteristic speed for each device, and incorporated into the verification process.

Once the components and their interconnections are established, the design is again transformed, this time into a physical design that describes specific geometric elements. This type of design often is referred to as a “layout” design. The geometric elements, which typically are polygons, define the shapes that will be created in various layers of material to manufacture the circuit. For digital circuits, automated place and route tools will be used to define the physical layouts, especially of wires that will be used to interconnect the circuit devices. Each layer of the microcircuit will have a corresponding layer representation in the layout design, and the geometric shapes described in a layer representation will define the relative locations of the circuit elements that will make up the circuit device. For example, shapes in the layer representation of a metal layer will define the locations of the metal wires used to connect the circuit devices. Custom layout editors, such as Mentor Graphics' IC Station or Cadence's Virtuoso, allow a designer to custom design the layout, which is mainly used for analog, mixed-signal, RF, and standard-cell designs.

Integrated circuit layout descriptions can be provided in many different formats. The Graphic Data System II (GDSII) format is a popular format for transferring and archiving two-dimensional graphical IC layout data. Among other features, it contains a hierarchy of structures, each structure containing layout elements (e.g., polygons, paths or poly-lines, circles and textboxes). Other formats include an open source format named Open Access, Milkyway by Synopsys, Inc., EDDM by Mentor Graphics, Inc., and the more recent Open Artwork System Interchange Standard (OASIS) proposed by Semiconductor Equipment and Materials International (SEMI). These various industry formats are used to define the geometrical information in IC layout designs that are employed to manufacture integrated circuits. Once the microcircuit device design is finalized, the layout portion of the design can be used by fabrication tools to manufacture the device using a photolithographic process.

Typically, a designer will perform a number of verification processes on the layout design. For example, the layout design may be analyzed to confirm that it complies with various design requirements, such as minimum spacings between geometric elements and minimum linewidths of geometric elements. In this process, a DRC (design rule checking) tool takes as input a layout in the GDSII standard format and a list of rules specific to the semiconductor process chosen for fabrication. A set of rules for a particular process is referred to as a run-set, rule deck, or just a deck. An example of the format of a rule deck is the Standard Verification Rule Format (SVRF) by Mentor Graphics Corporation.

The layout design are also analyzed to confirm that it accurately represents the circuit devices and their relationships described in the device design. A conventional LVS (layout versus schematic) process comprises two phases: extraction and comparison. In the extraction phase, a netlist is extracted from the layout design. The netlist includes not only types of and connectivity between the devices but also device parameters. In the comparison phase, the LVS tool compares the extracted netlist with the source netlist which is taken from the circuit schematic, and reports violations if any. LVS can be augmented by formal equivalence checking, which checks whether two circuits perform exactly the same function without demanding isomorphism.

As noted previously, curvilinear shapes present a challenge for conventional LVS tools as they are developed to process mainly Manhattan shapes. Each device in a layout design, whether electronic or photonic, is determined by a set of geometric parameters. A layout design typically uses Manhattan shapes to represent electronic devices. A LVS tool can easily identify Manhattan shapes and measure corresponding device parameters. The gate length and width, for example, are important device parameters as they are vital to ensuring correct performance of a metal-oxide-semiconductor field-effect transistor (MOSFET). On the other hand, photonic devices in a layout design often comprise curvilinear shapes. The boundary of a curvilinear shape is often formed with interconnected short straight line segments. A conventional LVS tool cannot easily recognize non-Manhattan shapes and extract their parameters. An efficient LVS flow that can verify devices using curvilinear shapes is highly desirable.

### Layout Versus Schematic Tool

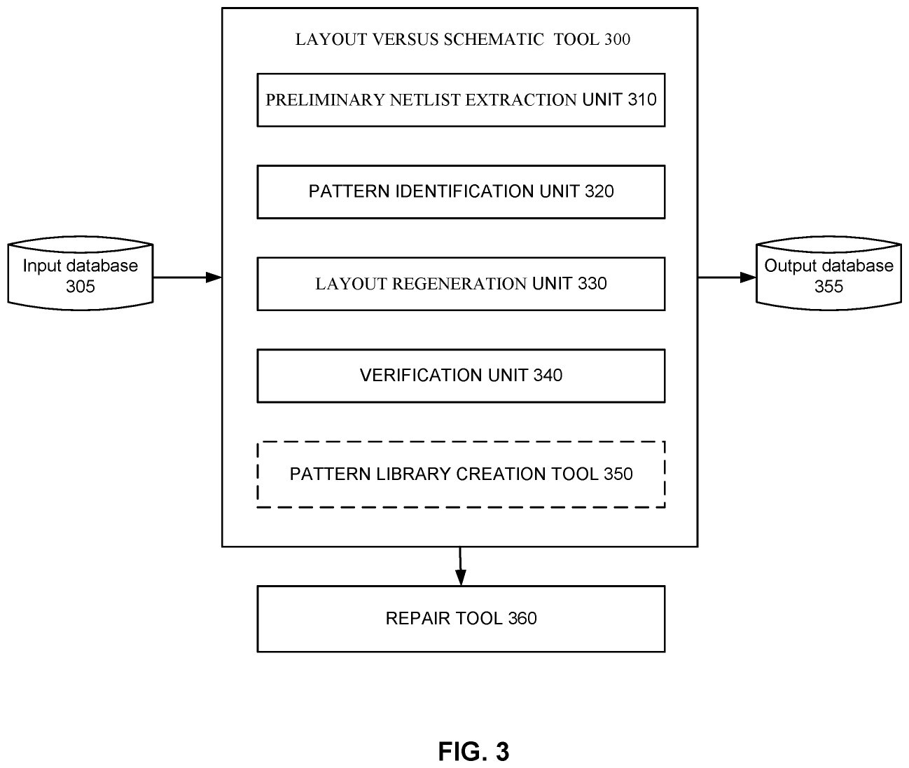

FIG. 3 illustrates an example of a layout versus schematic tool 300 that may be implemented according to various embodiments of the disclosed technology. The layout versus schematic tool 300 can use a different approach to process curvilinear shapes representing photonic devices. As seen in this figure, the layout versus schematic tool 300 includes a preliminary netlist extraction unit 310, a pattern identification unit 320, a layout regeneration unit 330, and a verification unit 340. Various implementations of the layout versus schematic tool 300 may cooperate with (or incorporate) one or more of a pattern library creation tool 350, a repair tool 360, an input database 305 and an output database 355.

As will be discussed in more detail below, the layout versus schematic tool 300 can receive a circuit design and an original layout design derived from the circuit design from the input database 305. The preliminary netlist extraction unit 310 can extract a preliminary netlist for photonic devices along with location and rotation information for each of the photonic devices from the original layout design based on treating each of the photonic devices as a black box. The pattern identification unit 320 can identify, in a group of geometric patterns for each of the photonic devices, a geometric pattern for the each of the photonic devices based on intended physical properties of the each of the photonic devices extracted from the circuit design. The layout regeneration unit 330 can generate a new layout design based on the identified geometric pattern for each of the photonic devices, the location and rotation information for each of the photonic devices, and the preliminary netlist. The verification unit 340 can compare geometric elements in each of the photonic devices in the new layout design with corresponding geometric elements in the original layout design. The layout versus schematic tool 300 can store results of the comparing in the output database 355. The pattern library creation tool 350 can create a group of geometric patterns for each type of the photonic devices. Optionally, the repair tool 360 can fix the problems identified in the results of the comparing.

As previously noted, various examples of the disclosed technology may be implemented by one or more computing systems, such as the computing system illustrated in FIGS. 1 and 2. Accordingly, one or more of the preliminary netlist extraction unit 310, the pattern identification unit 320, the layout regeneration unit 330, the verification unit 340, the pattern library creation tool 350, and the repair tool 360 may be implemented by executing programming instructions on one or more processors in one or more computing systems, such as the computing system illustrated in FIGS. 1 and 2. Correspondingly, some other embodiments of the disclosed technology may be implemented by software instructions, stored on a non-transitory computer-readable medium, for instructing one or more programmable computers/computer systems to perform the functions of one or more of the preliminary netlist extraction unit 310, the pattern identification unit 320, the layout regeneration unit 330, the verification unit 340, the pattern library creation tool 350, and the repair tool 360. As used herein, the term “non-transitory computer-readable medium” refers to computer-readable medium that are capable of storing data for future retrieval, and not propagating electro-magnetic waves. The non-transitory computer-readable medium may be, for example, a magnetic storage device, an optical storage device, or a solid state storage device.

It also should be appreciated that, while the preliminary netlist extraction unit 310, the pattern identification unit 320, the layout regeneration unit 330, the verification unit 340, the pattern library creation tool 350, and the repair tool 360 are shown as separate units in FIG. 3, a single computer (or a single processor within a master computer) or a single computer system may be used to implement some or all of these units at different times, or components of these units at different times.

With various examples of the disclosed technology, the input database 305 and the output database 355 may be implemented using any suitable computer readable storage device. That is, either of the input database 305 and the output database 355 may be implemented using any combination of computer readable storage devices including, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable storage devices may also include magnetic cassettes, magnetic tapes, magnetic disks or other magnetic storage devices, holographic storage devices, or any other non-transitory storage medium that can be used to store desired information. While the input database 305 and the output database 355 are shown as separate units in FIG. 3, a single data storage medium may be used to implement some or all of these databases.

### Process of Layout Versus Schematic for Photonic Devices

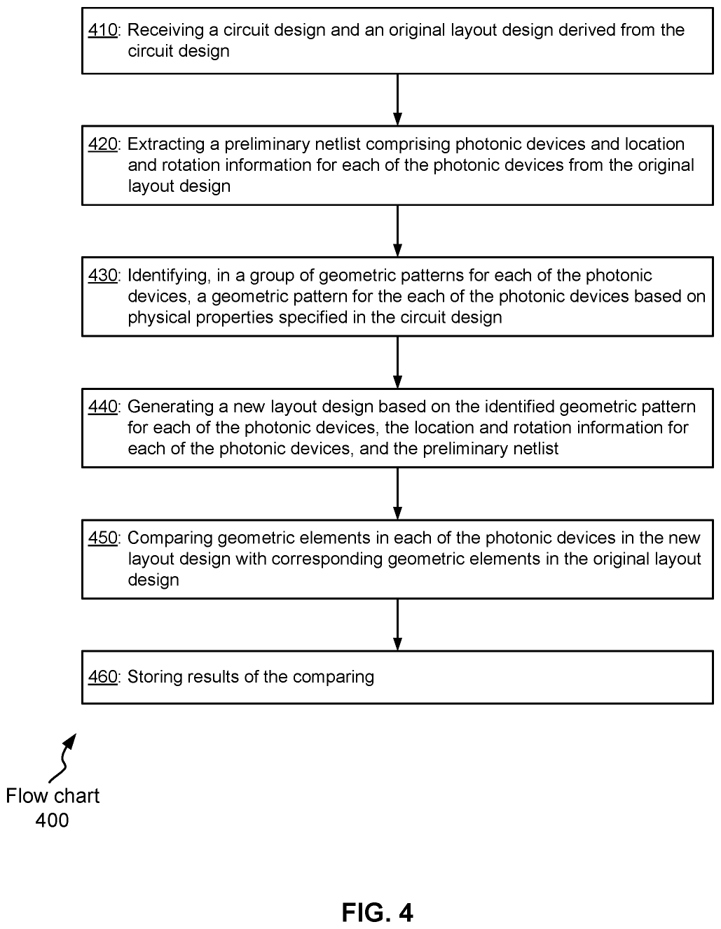

FIG. 4 illustrates a flowchart 400 showing a process of layout versus schematic for photonic devices that may be implemented according to various examples of the disclosed technology. For ease of understanding, methods of layout versus schematic for photonic devices that may be employed according to various embodiments of the disclosed technology will be described with reference to the layout versus schematic tool 300 in FIG. 3 and the flow chart 400 illustrated in FIG. 4. It should be appreciated, however, that alternate implementations of a layout versus schematic tool may be used to perform the methods of layout versus schematic for photonic devices illustrated by the flow chart 400 according to various embodiments of the disclosed technology. Likewise, the layout versus schematic tool 300 may be employed to perform other methods of layout versus schematic for photonic devices according to various embodiments of the disclosed technology.

In operation 410 of the flow chart 400, the layout versus schematic tool 300 receives, from the input database 505, a circuit design and an original layout design derived from the circuit design. The circuit design can be a full-chip design or a portion of a full-chip design. The circuit design may be described in the form of a netlist. The original layout design may be derived from the circuit design by using a place and route tool. The original layout design may be in the GDSII standard format or the OASIS standard format. The circuit design comprises photonic devices. Accordingly, the layout design comprises layout features having curved boundary lines or line segments. Photonic devices may comprise ring resonators, grating couplers, electro-optic modulators, or any combination thereof. Here, waveguides are also treated as photonic devices even though their primary function is transmitting photonic signals, unlike metal wires which transmit electronic signals and are not treated as devices. Except for parasitic elements (e.g., resistors, capacitors), the shape or size of a metal wire does not have a significant impact on the transmission of electronic signals. By contrast, the parameters of a waveguide such as the length, width and radius of curvature of a bend can significantly affect its operation and determine the modes of propagation of light in such a waveguide. Therefore, waveguide cannot be treated as perfect interconnects.

In operation 420, the preliminary netlist extraction unit 310 extracts a preliminary netlist comprising the photonic devices and location and rotation information for each of the photonic devices from the original layout design. In the extraction process, the preliminary netlist extraction unit 310 treats each of the photonic devices as a black box and extracts coordinates and rotational angle for each of the photonic devices. The coordinates of a photonic device may be the coordinates of a particular point (e.g., origins) associated with the black box for the photonic device. In the black box approach, the preliminary netlist extraction unit 310 ignores physical parameters for geometric elements in each of the photonic devices. All of these black boxes representing the photonic devices can be orthogonally oriented. If a photonic device is non-orthogonally placed, it can be treated as being rotated inside the black box. The rotation angel is recorded as an important parameter for the photonic device.

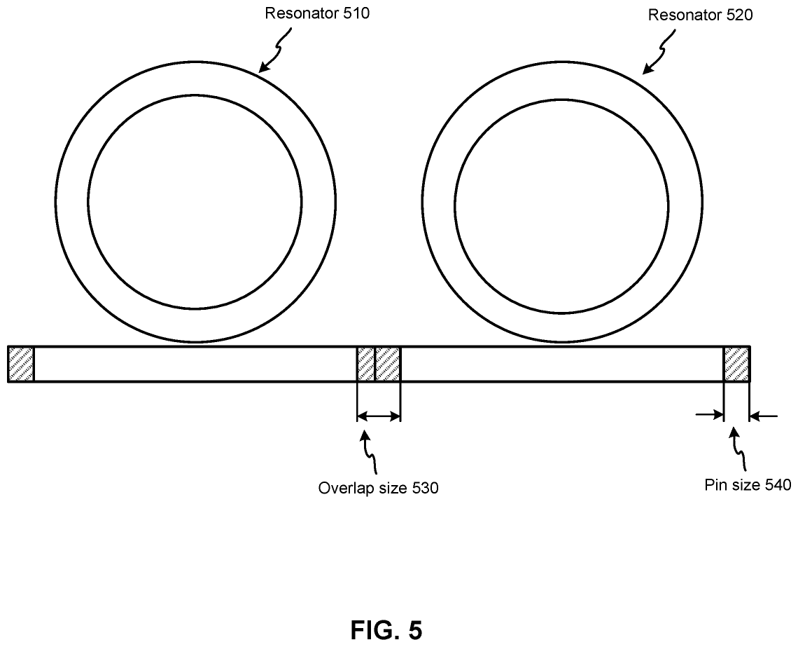

While generating the preliminary netlist, the preliminary netlist extraction unit 310 can verify that each photonic device is of the right type and that the connectivity between the photonic devices is correct. A photonic device may overlap another photonic device. The preliminary netlist extraction unit 310 can check whether the overlap occurs within acceptable limits to establish a connection between the two photonic devices. FIG. 5 illustrates an example of an overlap between two ring resonators 510 and 520. The preliminary netlist extraction unit 310 extracts the coordinates and rotation values of the two ring resonators 510 and 520 but not the parameters for the ring and straight waveguide parts such as radius and width. The preliminary netlist extraction unit 310 also checks an overlap size 530 between the pins of the two ring resonators 510 and 520. An acceptable overlap distance of pins of two photonic devices of the same type may be set to be double pin size. Here, the overlap size 530 is smaller than double pin size 540, so the pins of the two photonic devices 510 and 520 are touching. The preliminary netlist extraction unit 310 can report that the connectivity between the two ring resonators 510 and 520 is established.

The preliminary netlist extraction unit 310 can be implemented based on engines in a commercial LVS tool, such as those in the Calibre family of software tools available from Siemens Industry Software Inc., 5800 Granite Parkway, Plano, Texas. The Calibre LVS tool has a LVS Black Box function, which the preliminary netlist extraction unit 310 can utilize.

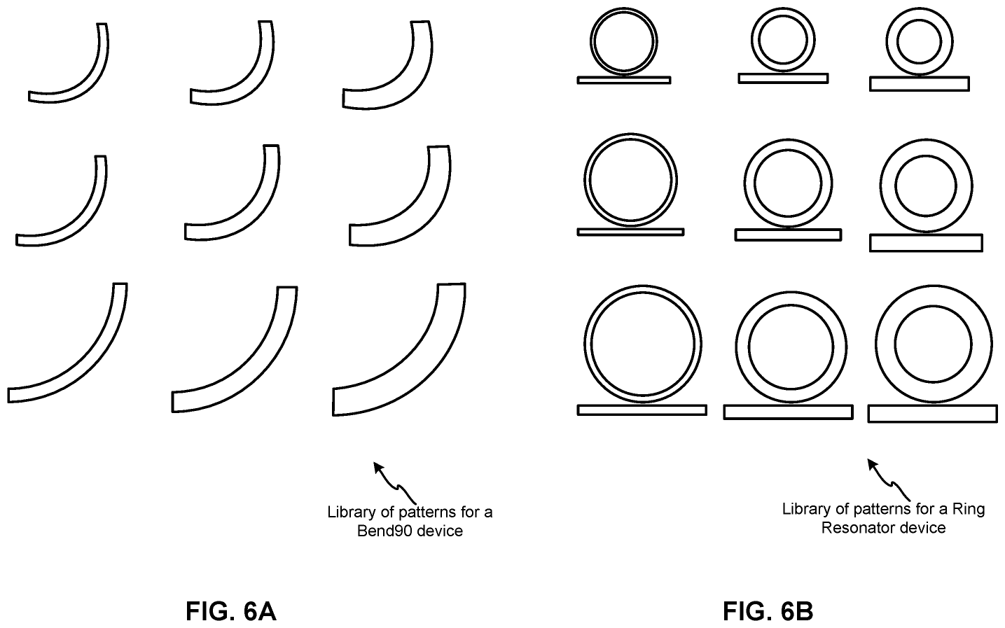

Referring back to FIG. 4, in operation 430, the pattern identification unit 320 identifies, in a group of geometric patterns for each of the photonic devices, a geometric pattern for the each of the photonic devices based on physical properties of the each of the photonic devices extracted specified in the circuit design. The pattern library creation tool 350 can be employed to create a group of geometric patterns for each type of the photonic devices. First, the pattern library creation tool 350 can use a layout editor to create a geometric pattern for a photonic device. Next, the pattern library creation tool 350 can alter characteristic features of the photonic device to generate a plurality of geometric patterns. The pattern library creation tool 350 can then capture physical properties of these patterns and store them in a library. The FIG. 6A illustrates an example of a group of geometric patterns for a Bend90 device; and FIG. 6B illustrates an example of a group of geometric patterns for a ring resonator device. While only nine patterns are shown for each of the photonic devices, each group of geometric patterns can have thousands of geometric patterns. The library creation process can be performed before or in the process of layout versus schematic for photonic devices illustrated by the flow chart 400. The groups of geometric patterns can be reused for various circuit designs and be updated with new devices being used.

To search for the geometric pattern for each of the photonic devices, the pattern identification unit 320 can first extract the specified physical properties for a photonic device from the circuit design. For example, for a ring resonator, the specified physical properties may comprise radius, width, and gap spacing; and for a bend90 device, the specified physical properties may comprise radius and width. Then the pattern identification unit 320 can use the name identifier for the photonic device to locate a group of geometric patterns. Finally, the pattern identification unit 320 can compare the specified physical properties with the physical properties for each of the geometric patterns in the group of geometric patterns which are stored in the library prepared by the pattern library creation tool 350 to determine whether a match within the defined tolerance values is found. If the answer is yes, the pattern library creation tool 350 can associate the identified geometric pattern with the photonic device. This can be repeated for each of the photonic devices in the circuit design.

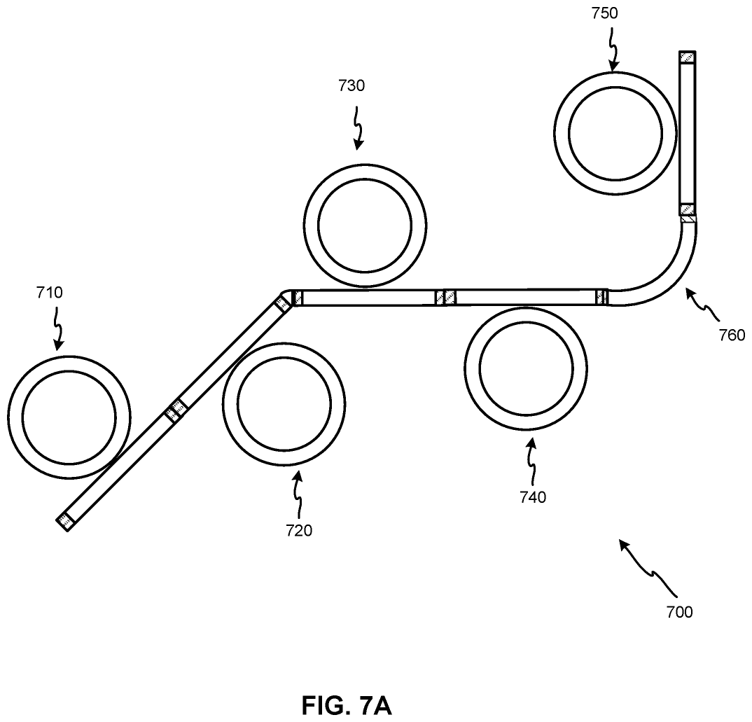

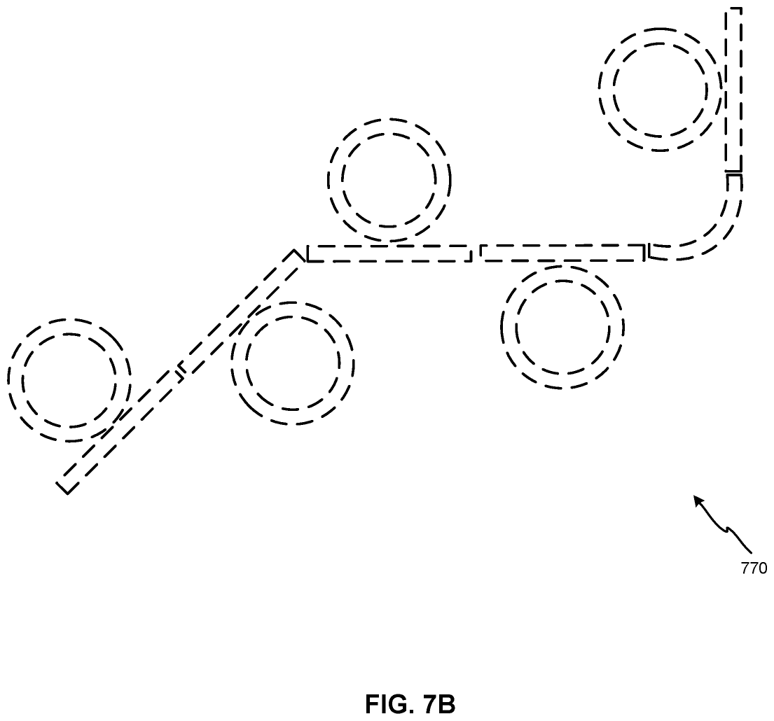

Referring back to FIG. 4, in operation 440, the layout regeneration unit 330 generates a new layout design based on the identified geometric pattern for each of the photonic devices, the location and rotation information for each of the photonic devices, and the preliminary netlist. The layout regeneration unit 330 can generate an OASIS file or a GDSII file, in which the identified geometric pattern for each of the photonic devices is placed according to the location and rotation information. The new layout design generation process may also be referred to as re-instantiation. FIG. 7A illustrates an example of an original layout design 700 for a circuit design. The original layout design 700 comprises five ring resonators 710, 720, 730, 740 and 750, and a bend90 device 760. The ring resonators 710 and 720 can be treated as one type of devices (45-degree ring resonators); the ring resonators 730, 740 and 750 can be treated as a type of regular ring resonators. For the type of 45-degree ring resonators, the rotational angles are 0 degree and 180 degree for the ring resonators 710 and 720, respectively. For the type of regular ring resonators, the rotational angles are 0 degree, 180 degree, and 90 degree for the ring resonators 730, 740, and 750, respectively. The connectivity between all these devices can be verified in the operation 420. FIG. 7B illustrates an example of a layout design 770 generated by placing the geometric patterns identified from the groups of geometric patterns based on the location and rotation information and the preliminary netlist extracted from the layout deign shown in FIG. 7A.

Referring back to FIG. 4, in operation 450, the verification unit 340 compares geometric elements in each of the photonic devices in the new layout design generated in the operation 440 with corresponding geometric elements in the original layout design. Using the new layout, the verification unit 340 can locate geometric components of a geometric pattern for a photonic device in the original layout and determine whether these geometric components in the two layouts match based on preset criteria. This can avoid using complex coding to describe a geometric pattern which may encounter snapping issues and false violations.

In operation 470, the layout versus schematic tool 300 stores the comparison results in the output database 355.

If the comparison results indicate some problems of the original layout design, the repair tool 360 can try to fix these problems.

### CONCLUSION

While the disclosed technology has been described with respect to specific examples including presently preferred modes of carrying out the disclosed technology, those skilled in the art will appreciate that there are numerous variations and permutations of the above described systems and techniques that fall within the spirit and scope of the disclosed technology as set forth in the appended claims. For example, while specific terminology has been employed above to refer to electronic design automation processes, it should be appreciated that various examples of the disclosed technology may be implemented using any desired combination of electronic design automation processes.

What is claimed is:

1. A method, executed by at least one processor of a computer, comprising:
receiving a circuit design and an original layout design derived from the circuit design, the circuit design comprising photonic devices, the photonic devices comprising waveguides;
extracting a preliminary netlist comprising the photonic devices and location and rotation information for each of the photonic devices from the original layout design, wherein the extracting a preliminary netlist treats each of the photonic devices as a black box;
identifying, in a group of geometric patterns for each of the photonic devices, a geometric pattern for the each of the photonic devices based on physical properties of the each of the photonic devices specified in the circuit design;
generating a new layout design based on the identified geometric pattern for each of the photonic devices, the location and rotation information for each of the photonic devices, and the preliminary netlist;
comparing geometric elements in each of the photonic devices in the new layout design with corresponding geometric elements in the original layout design; and
storing results of the comparing.

2. The method recited in claim 1, further comprising:
repairing problems identified in the results of the comparing.

3. The method recited in claim 1, wherein the extracting a preliminary netlist comprises verifying connectivity between the photonic devices.

4. The method recited in claim 1, wherein the group of geometric patterns is generated by using a layout editing tool to create one geometric pattern for a type of the each of the photonic devices and then to vary physical properties of the one geometric pattern to generate more geometric patterns for the type of the each of the photonic devices.

5. The method recited in claim 1, wherein photonic devices in the photonic devices that are of the same type but have different rotational angles are treated as different photonic devices.

6. One or more non-transitory computer-readable media storing computer-executable instructions for causing one or more processors to perform a method, the method comprising:
receiving a circuit design and an original layout design derived from the circuit design, the circuit design comprising photonic devices, the photonic devices comprising waveguides;
extracting a preliminary netlist comprising the photonic devices and location and rotation information for each of the photonic devices from the original layout design, wherein the extracting a preliminary netlist treats each of the photonic devices as a black box;
identifying, in a group of geometric patterns for each of the photonic devices, a geometric pattern for the each of the photonic devices based on physical properties of the each of the photonic devices specified in the circuit design;
generating a new layout design based on the identified geometric pattern for each of the photonic devices, the location and rotation information for each of the photonic devices, and the preliminary netlist;
comparing geometric elements in each of the photonic devices in the new layout design with corresponding geometric elements in the original layout design; and
storing results of the comparing.

7. The one or more non-transitory computer-readable media recited in claim 6, wherein the method further comprises: repairing problems identified in the results of the comparing.

8. The one or more non-transitory computer-readable media recited in claim 6, wherein the extracting a preliminary netlist comprises verifying connectivity between the photonic devices.

9. The one or more non-transitory computer-readable media recited in claim 6, wherein the group of geometric patterns is generated by using a layout editing tool to create one geometric pattern for a type of the each of the photonic devices and then to vary physical properties of the one geometric pattern to generate more geometric patterns for the type of the each of the photonic devices.

10. The one or more non-transitory computer-readable media recited in claim 6, wherein photonic devices in the photonic devices that are of the same type but have different rotational angles are treated as different photonic devices.

11. A system, comprising:
one or more processors, the one or more processors programmed to perform a method, the method comprising:
receiving a circuit design and an original layout design derived from the circuit design, the circuit design comprising photonic devices, the photonic devices comprising waveguides;
extracting a preliminary netlist comprising the photonic devices and location and rotation information for each of the photonic devices from the original layout design, wherein the extracting a preliminary netlist treats each of the photonic devices as a black box;
identifying, in a group of geometric patterns for each of the photonic devices, a geometric pattern for the each of the photonic devices based on physical properties of the each of the photonic devices specified in the circuit design;
generating a new layout design based on the identified geometric pattern for each of the photonic devices, the location and rotation information for each of the photonic devices, and the preliminary netlist;
comparing geometric elements in each of the photonic devices in the new layout design with corresponding geometric elements in the original layout design; and
storing results of the comparing.

12. The system recited in claim 11, wherein the method further comprises: repairing problems identified in the results of the comparing.

13. The system recited in claim 11, wherein the extracting a preliminary netlist comprises verifying connectivity between the photonic devices.

14. The system recited in claim 11, wherein the group of geometric patterns is generated by using a layout editing tool to create one geometric pattern for a type of the each of the photonic devices and then to vary physical properties of the one geometric pattern to generate more geometric patterns for the type of the each of the photonic devices.

15. The system recited in claim 11, wherein photonic devices in the photonic devices that are of the same type but have different rotational angles are treated as different photonic devices.
